(19) United States
(12) Patent Application Publication
(10) Pub. No.: US 2005/0061528 A1
(43) Pub. Date: Mar. 24, 2005

(54) Shielding device, circuit assembly and method of manufacture

(76) Inventors: Esen Bayar, London (GB); Charles Joseph Caddick, Royston (GB); Tacar Gokdemir, London (GB); Nigel Richard Watson, Widdington (GB)

Correspondence Address: PILLSBURY WINTHROP, LLP, P.O. BOX 10500, MCLEAN, VA, 22102, US

(21) Appl. No.: 10/497,917

(22) PCT Filed: Nov. 25, 2002
(86) PCT No.: PCT/GB02/05286

Related U.S. Application Data
(60) Provisional application No. 60/336,171, filed on Dec. 6, 2001.

(51) Int. Cl. H05K 5/02

(52) U.S. Cl. 174/51

(57) ABSTRACT

A shielding device (102) is provided for a circuit board that has components thereon which operate at 10 GHz or above. The shielding device (102) has a face with a plurality of component recesses (104-109) therein each for receiving a portion of at least one component. At least some of the shielding device (102) is formed of a material that is absorptive of electromagnetic radiation having a frequency of about 10 GHz or above. The electrical properties of the material and the dimensions of the component recesses (104-109) are arranged such that, when the shielding device (102) is used in conjunction with a circuit board, the shielding device (102) suppresses undesired propagation of electromagnetic radiation between components of the circuit board.

The present invention relates to a shielding device for a circuit board, to a circuit assembly comprising a circuit board and a shielding device, and to a method of manufacturing a shielding device.

It has long been recognised that there is a great tendency for unwanted electromagnetic leakage from one component of a circuit to another, especially when operating at high radio and microwave frequencies and especially where the space available for the circuit is limited. This is exacerbated by the fact that it is also often desirable to minimise the spacing between different components in a high or microwave frequency circuit arrangement so as to reduce the effects of propagation time.

Early circuits operating at high frequencies were formed of discrete components. Where a set of discrete components formed a first sub-circuit operating at one frequency and the circuit further comprised a second sub-circuit operating at a different frequency, the circuit as a whole being formed in a metal enclosure, isolation between the sub-circuits was attempted by dividing up the enclosure by metal partition walls and disposing each of the sub-circuits in a separate compartment. Communication between the compartments was by feed-through elements.

More modern circuitry, typically using microstrip technology with components secured to a circuit board or similar substrate, was developed to have screening performed by a lid compartmentalised by metal walls, the walls being disposed in close proximity to the components so as to subdivide the circuitry into sub-circuits. By the use of such separating walls, the intention is to reduce interaction and interference between components on the circuit board so that, from the point of view of cross-talk and radiation leakage, the sub-circuits approach the desired state of being mutually infinitely separated. The use of metal or metallised dividing walls is disadvantageous as multiple reflections may occur, and thus complete analysis of the performance of a cavity defined by such walls is practically impossible.

Given the use of centrimetric and sub-centrimetric wavelengths, the wavelength of the electromagnetic waves in question has an impact upon the size of any cavity in which a circuit is disposed. Undesired resonance effects may occur if the cavity has a path length equal to one wavelength of the frequency of concern.

Prior art arrangements do not provide the dual constraints of adequate isolation between circuit components and lack of effect on desired operation of those components. One consequence of this is that known circuits tend to have wider separation between components than is strictly necessary merely so as to improve the electrical isolation. This may have the result of causing the resulting circuit to be in a housing that is generally larger than is strictly necessary.

According to a first aspect of the present invention, there is provided a shielding device for a circuit board having components thereon which in use operate at 10 GHz or above, the shielding device having a face with a plurality of component recesses therein each for receiving a portion of at least one component, at least some of the shielding device being formed of a material that is absorptive of electromagnetic radiation having a frequency of about 10 GHz or above, the electrical properties of the material and the dimensions of the component recesses being arranged such that, when the shielding device is used in conjunction with a said circuit board, the shielding device suppresses undesired propagation of electromagnetic radiation between components of a said circuit board.

The use of radiation absorbing material in conjunction with the component recesses means that components on a circuit board can be shielded effectively from one another and minimises or removes altogether reflections which might otherwise occur. Moreover, undesired propagation modes (such as second and higher order modes) between components can be suppressed. The shielding device can be arranged such that the components experience conditions close to the preferred “infinite separation” state. The device may be a unitary component or may be multipart, for example having a plastics main body part and a rubber insert. The component recesses will typically have a size less than one wavelength of the operating signals of the associated circuit components.

Preferably the shielding device has at least one channel recess in said face which connects two component recesses for permitting desired propagation of electromagnetic radiation between components received in part in said two component recesses in use. Since the material absorbs electromagnetic radiation, this embodiment provides a channel recess over a conductive element connecting two components such that the spacing of the face of the shielding device from the conductive element is sufficient to allow signal propagation between the two components and reduces capacitive and other suppressing effects.

The radiation absorbing material may comprise iron-loaded rubber, carbon-loaded plastics or a mixture thereof or other materials of similar properties. Iron-loaded rubber is a relatively flexible resilient material and thus is used to advantage where such properties are desirable. In contrast, carbon-loaded plastics may be more rigid and this property is important in some embodiments. Moreover, carbon-loaded plastics is generally cheaper and easier to mould than iron-loaded rubber. Alternatively or additionally, radiation absorptive paint, such as iron or carbon doped paint, may be coated over walls, parts of walls, etc., as required.

According to a second aspect of the present invention, there is provided a circuit assembly comprising a circuit board and a shielding device disposed on the circuit board, the circuit board having a plurality of components thereon which in use operate at a frequency of about 10 GHz or above, the shielding device having a face with a plurality of component recesses therein each for receiving a portion of at least one of said components, at least some of the shielding device being formed of a material that is absorptive of electromagnetic radiation having a frequency of about 10 GHz or above, the electrical properties of the material and the dimensions of the component recesses being arranged such that the shielding device suppresses undesired propagation of electromagnetic radiation between the components of the circuit board.

The circuit board may comprise at least one conductive member connected to at least two of said components for propagating signals at about 10 GHz or above between said at least two of said components, and the shielding device may have at least one channel recess in said face that corresponds to said conductive member and that connects two component recesses for permitting desired propagation of electromagnetic radiation between said at least two of said components received in part in said two component recesses in use.

Said material may comprise iron-loaded rubber or carbon-loaded plastics or another material having similar absorptive properties, or a mixture of such materials. Again, radiation absorptive paint, such as iron or carbon doped paint, may be coated over walls, parts of walls, etc., as required.

The shielding device may be urged into engagement with the circuit board. The ability to urge the shielding device into engagement with the circuit board is significant where the circuit assembly as a whole may subject to movement or vibration. A lid on an enclosure containing the circuit board may be provided such that the lid presses either directly or indirectly on the shielding device.

The circuit board and the shielding device may be disposed within a metal case. A metal case provides the effect of a Faraday cage so that radiation from within the case is prevented from leaking to the outside and radiation from outside the case is prevented from interfering with the components on the circuit board.

Preferably the circuit board comprises transmit circuitry and receive circuitry which operate in use at a frequency of about 10 GHz or above.

The frequency or frequencies of operation may for example be in any of the X, Ku, K, Ka and U bands (from 8 GHz to 60 GHz).

According to a third aspect of the invention there is a provided a method of manufacturing a shielding device for use with a circuit board having plural components thereon which form a circuit which in use operates at 10 GHz or above, the shielding device having a face with a plurality of component recesses therein each for receiving a portion of at least one component, at least some of the shielding device being formed of a material that is absorptive of electromagnetic radiation having a frequency of about 10 GHz or above, the electrical properties of the material and the dimensions of the component recesses being arranged such that, when the shielding device is used in conjunction with a said circuit board, the shielding device suppresses undesired propagation of electromagnetic radiation between components of a said circuit board, the method comprising the steps of: establishing signal levels present in use at each of the components; establishing the level of electromagnetic leakage from each radiative part of the circuit that can be tolerated at other parts of the circuit; selecting one or more materials for the shielding device on the basis of said levels to achieve a desired performance of said circuit; selecting the dimensions of the said component recesses and the spacings between said component recesses to achieve a desired performance of said circuit; and, forming said shielding device in accordance with said selection steps.

A circuit assembly comprising a circuit board and a shielding device manufactured in accordance with this method can be compact and made in a cost-effective way.

The shielding device may have at least one channel recess in said face which connects two component recesses for permitting desired propagation of electromagnetic radiation between components received in part in said two component recesses in use, and the method may comprise the step of selecting the dimensions of said channel recess to achieve a desired performance of said circuit.

Said material or materials may be selected from the group including iron-loaded rubber and carbon-loaded plastics. Again, radiation absorptive paint, such as iron or carbon doped paint, may be coated over walls, parts of walls, etc., as required.

The circuit may be for example a transmit-receive module or sub-module.

The circuit board and the shielding device may be designed to support fully automated, part automated or manual assembly lines.

Embodiments of the present invention will now be described by way of example with reference to the accompanying drawings, in which:

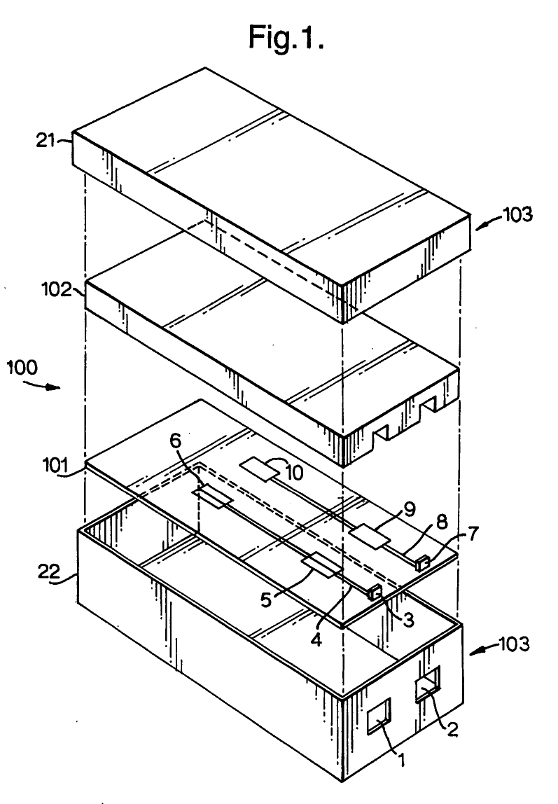

FIG. 1 shows schematically an exploded view of an example of a transmit-receive device including an example of a shielding device in accordance with the present invention;

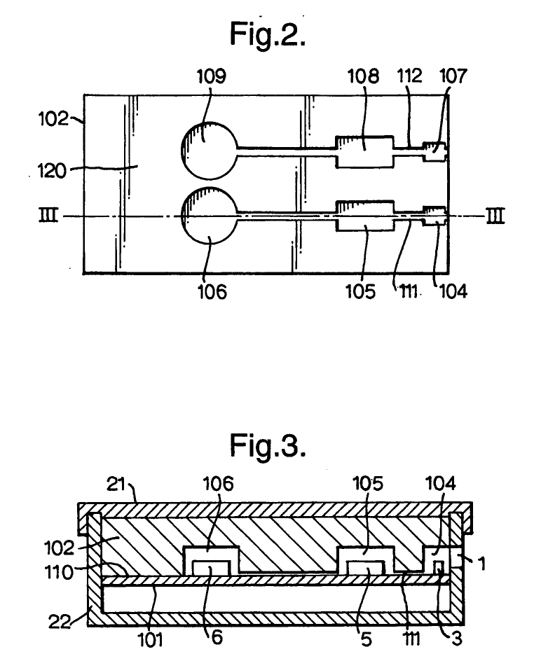

FIG. 2 shows schematically a plan view of the shielding device of FIG. 1; and,

FIG. 3 shows a cross-section through the transmit-receive device of FIG. 1 effectively along III-III of FIG. 2.

Referring first to FIG. 1, a transmit-receive device 100 operating in one of the X, Ku, K, Ka, U bands, for example at 28 GHz, includes a circuit board 101, a shielding device 102 and an enclosure 103. It will be understood that only some, exemplary components of the circuit board 101 are shown.

A first transmit/receive port 1 and a second transmit/receive port 2 are connected in use via respective waveguides (not shown) to one or more transmit/receive antennas (not shown). In its transmit mode, the first port 1 has an emission probe 3 for launching a signal into the associated waveguide from a transmit strip line 4 on the circuit board 101. The transmit strip line 4 is fed by a gain stage 5 which is in turn connected to the output of a first mixer 6. The mixer 6 is fed from a frequency source and a modulation source (not shown). In its receive mode, the second port 2 has a pick-up probe 7 for receiving a signal from the associated waveguide and interfacing the signal to a receive strip line 8. The receive strip line 8 is connected to a gain-detector stage 9 whose output is connected to a second mixer 10 which derives an intermediate frequency signal. Power and coupling components (not shown) are also provided.

The circuit board 101 is disposed in the enclosure 103. The enclosure 103 in this example is a metal box 103 having a metal lid 21 and a metal body 22. The lid 21 is secured to the body 22 such that the box 103 itself forms a Faraday cage, the principal purpose of which is to screen internal components from external electromagnetic radiation, but also to minimise or prevent leakage of electromagnetic radiation out of the box 103. The lid 21 engages the shielding device 102 which will be further described with respect to FIG. 2.

Referring now to FIG. 2, the shielding device 102 in this example is formed entirely or at least in part of a radiation-absorptive-material, such as iron-loaded rubber or carbon-loaded plastics or other material of similar properties or a mixture of any of these materials. Such radiation absorbing materials are known in themselves. The material preferably has an electrical conductivity that allows bulk RF transmission whilst at the same time being sufficiently electrically conducting to allow some RF currents to flow in the material itself.

Desired values of electrical conductivity and attenuation can be achieved at a basic level by selection of the type of material. In some cases it is desirable to provide different properties at different parts of the shielding device. This may be achieved either by forming a composite shielding device of two or more different materials, by varying the loading or doping of the basic material, or by a combination of the two methods.

The absorptive properties can be modified by using absorptive paints, such as iron or carbon-loaded paints. Reflective paints, such as glossy or silver paints may also be used to tailor the properties at selected locations. In either case, such paints may be coated over walls, parts of walls, etc., as required.

The material preferably has resilience and, as will be seen in FIG. 3, the shielding device 102 is preferably urged by the lid 21 into engagement with the circuit board 102. The lid 21 may be connected to the body 22 by one or more of screws, clips, rivets, etc. The shielding device has a number of cavities 104-109 each for receiving a portion of one of the gain elements 5,6,9,10 and the probes 3,7 of the underlying circuit board 102. The term “gain” is used here to indicate both gains in excess of unity and fractional gains.

The cavities 104-109 are disposed in one face 120 of the shielding device 102 and in this embodiment do not pass through the entire thickness of the shielding device 102. Between the cavities 104-109 are lands 110 of full thickness.

The dimensions of the cavities 104-109 are selected in conjunction with the arrangement of the material(s) of the shielding device 102 so as to allow the desired performance of the circuit element or elements within the cavities 104-109 on the basis of the conductivity of the material and the signal levels that are established as being presented by the components in use.

The shielding device 102 further has channel recesses 111,112 interconnecting the cavities and disposed above and along the strip lines 4,8 of the underlying circuit board 101. The dimensions of the channel recesses 111,112 are chosen to enable propagation along the corresponding strip line 4,8. In the embodiment described, the lands 110 of the shielding device 102, which surround the cavities 104-109 and the channel recesses 111,112, are in close engagement with the circuit board 101 so as to attenuate leakage signals of the circuit underlying it. It will be understood however that circumstances may arise in which continuous contact between the walls of the shielding device 102 and the underlying circuit board 101 may not always be desirable.

As previously mentioned, the ability to tailor the shielding device to the circuit may be enhanced by differential doping of the radiation absorbing material to provide regions of different conductivity where appropriate and/or by use of reflective or absorptive paints over selected portions.

The ability to provide physical support to the components on the circuit board and to the board itself is significant in applications where the transmit-receive device is either portable or is designed to move or may be subject to shock or vibration (such as when mounted on the exterior of a building). For example, the transmit-receive device may be connected to an antenna rotation device which may subject the transmit-receive device to starting and stopping torque and also to vibration. The ability of the shielding device to provide support is thus highly significant.

The shielding device also enables tailoring of the properties of the shielding device to the underlying circuit components. It is thus possible to provide a circuit configuration that is smaller than that provided by the prior art.

To design the shielding device, the RF signal levels present at each part of the circuit are established and then it is calculated how much leakage can be tolerated from each radiative part of the circuit to all other parts of the circuit. The material of the shielding device is then selected and the dimensions of the cavities and any channel recesses in the shielding device are calculated to provide the desired attenuation and conductivity. The spacing of the gain or attenuation blocks is then calculated so as to provide a desired amount of electrical isolation/attenuation. The attenuation levels may be selected to be different at different frequencies and propagation modes. This enables suppression of undesired electromagnetic propagations whilst exhibiting minimal effect on the propagation of the desired signal. The layout of the circuit is then determined so as to minimise the overall extent of the circuit, thus enabling compact and cost effective microwave structures to be provided.

The shielding device, which is normally continuous with the circuit board to provide a generally enclosed cavity also serves to prevent any reflections within the enclosure 103.

An embodiment of the present invention has been described with particular reference to the example illustrated. However, it will be appreciated that variations and modifications may be made to the example described within the scope of the present invention.

1. A shielding device for a circuit board having components thereon which in use operate at 10 GHz or above, the shielding device having a face with a plurality of component recesses therein each for receiving a portion of at least one component, at least some of the shielding device being formed of a material that is absorptive of electromagnetic radiation having a frequency of about 10 GHz or above, the electrical properties of the material and the dimensions of the component recesses being arranged such that, when the shielding device is used in conjunction with a said circuit board, the shielding device suppresses undesired propagation of electromagnetic radiation between components of a said circuit board.

2. A shielding device according to claim 1, wherein the shielding device has at least one channel recess in said face which connects two component recesses for permitting desired propagation of electromagnetic radiation between components received in part in said two component recesses in use.

3. A shielding device according to claim 1, wherein said material comprises iron-loaded rubber.

4. A shielding device according to claim 1, wherein said material comprises carbon-loaded plastics.

5. A circuit assembly comprising a circuit board and a shielding device disposed on the circuit board, the circuit board having a plurality of components thereon which in use operate at a frequency of about 10 GHz or above, the shielding device having a face with a plurality of component recesses therein each for receiving a portion of at least one of said components, at least some of the shielding device being formed of a material that is absorptive of electromagnetic radiation having a frequency of about 10 GHz or above, the electrical properties of the material and the dimensions of the component recesses being arranged such that the shielding device suppresses undesired propagation of electromagnetic radiation between the components of the circuit board.

6. A circuit assembly according to claim 5, wherein the circuit board comprises at least one conductive member connected to at least two of said components for propagating signals at about 10 GHz or above between said at least two of said components, and wherein the shielding device has at least one channel recess in said face that corresponds to said conductive member and that connects two component recesses for permitting desired propagation of electromagnetic radiation between said at least two of said components received in part in said two component recesses in use.

7. A circuit assembly according to claim 5, wherein said material comprises iron-loaded rubber.

8. A circuit assembly according to claim 5, wherein said material comprises carbon-loaded plastics.

9. A circuit assembly according to claim 5, wherein the shielding device is urged into engagement with the circuit board.

10. A circuit assembly according to any claim 5, wherein the circuit board and the shielding device are disposed within a metal case.

11. A circuit assembly according to claim 5, wherein the circuit board comprises transmit circuitry and receive circuitry, said transmit circuitry and receiver circuitry in use operating at frequencies of about 10 GHz or above.

12. A method of manufacturing a shielding device for use with a circuit board having plural components thereon which form a circuit which in use operates at 10 GHz or above, the shielding device having a face with a plurality of component recesses therein each for receiving a portion of at least one component, at least some of the shielding device being formed of a material that is absorptive of electromagnetic radiation having a frequency of about 10 GHz or above, the electrical properties of the material and the dimensions of the component recesses being arranged such that, when the shielding device is used in conjunction with a said circuit board, the shielding device suppresses undesired propagation of electromagnetic radiation between components of a said circuit board, the method comprising the steps of:
establishing signal levels present in use at each of the components;
establishing the level of electromagnetic leakage from each radiative part of the circuit that can be tolerated at other parts of the circuit;
selecting one or more materials for the shielding device on the basis of said levels to achieve a desired performance of said circuit;
selecting the dimensions of the said component recesses and the spacings between said component recesses to achieve a desired performance of said circuit; and,
forming said shielding device in accordance with said selection steps.

13. A method according to claim 12, wherein the shielding device has at least one channel recess in said face which connects two component recesses for permitting desired propagation of electromagnetic radiation between components received in part in said two component recesses in use, the method comprising the step of selecting the dimensions of said channel recess to achieve a desired performance of said circuit.

14. A method according to claim 12, wherein said material or materials are selected from the group including iron-loaded rubber and carbon-loaded plastics.
